(19) United States
(12) Patent Application Publication
(10) Pub. No.: US 2014/0159052 A1
(43) Pub. Date: Jun. 12, 2014

(54) METHOD AND STRUCTURE FOR TRANSISTOR WITH REDUCED DRAIN-INDUCED BARRIER LOWERING AND ON RESISTANCE

(71) Applicant: GLOBALFOUNDRIES INC., Grand Cayman (KY)

(72) Inventors: Jinping Liu, Hopewell Junction, NY (US); Yi Qi, Fishkill, NY (US); Xiaodong Yang, Hopewell Junction, NY (US)

(73) Assignee: GLOBALFOUNDRIES INC., Grand Cayman (KY)

(21) Appl. No.: 13/710,639

(22) Filed: Dec. 11, 2012

(51) Int. Cl. H01L 29/78; H01L 21/02

(52) U.S. Cl. CPC H01L 29/78; H01L 21/02367
USPC 257/77; 257/192; 438/478

(57) ABSTRACT

Embodiments of the invention provide an improved method and structure for a transistor with reduced DIBL and R_{ON}. A sigma cavity is formed in a semiconductor substrate adjacent to a transistor. The sigma cavity is filled with an epitaxially grown semiconductor material that also serves as a stress-inducing region for the purposes of increasing carrier mobility. The epitaxially grown semiconductor material is doped with a reverse doping profile. A lightly doped region lines the interior of the sigma cavity, followed by an undoped region, followed by a heavily doped region. The shape of the lightly doped region is such that it is thicker adjacent to the channel, which reduces R_{ON}, and thinner below the channel, which reduces DIBL.

### FIELD OF THE INVENTION

The present invention relates generally to semiconductor fabrication and, more particularly, to a method and structure for a transistor with reduced drain-induced barrier lowering (DIBL) and on resistance (R_{ON}).

### BACKGROUND

The semiconductor fabrication industry has a goal to achieve individual devices with smaller physical dimensions. The trend in the industry is towards thinner device regions and gate oxides, shorter channels, and lower power consumption.

However, smaller critical dimensions often create some performance drawbacks. In particular, a known category of performance limitations known as short channel effects become more significant as the length of the channel of CMOS devices is reduced. One particular short-channel effect in CMOS devices, known as Drain Induced Barrier Lowering (DIBL), is significantly responsible for the degradation of performance in transistor devices. DIBL is a reduction in the potential barrier between the drain and source as the channel length shortens. When the drain voltage is increased, the depletion region around the drain increases, and the drain region electric field reduces the channel potential barrier which results in an increased off-state or leakage current between the source and drain.

Another important parameter for a transistor is its on-resistance (R_{ON}), which is the series resistance of the source, channel, and drain. For device performance purposes, it is desirable to reduce DIBL and R_{ON} as much as possible.

### SUMMARY OF THE INVENTION

In general, embodiments of the invention provide an improved method and structure for a transistor with reduced DIBL and R_{ON}. A sigma cavity is formed in a semiconductor substrate adjacent to a transistor. The sigma cavity is filled with an epitaxially grown semiconductor material that also serves as a stress-inducing region for the purposes of increasing carrier mobility. The epitaxially grown semiconductor material is doped with a reverse doping profile, which is lightly doped at the beginning. A lightly doped region lines the interior of the sigma cavity, followed by an undoped region, followed by a heavily doped region. The shape of the lightly doped region is such that it is thicker adjacent to the channel, and thinner below the channel. The shape of the undoped region is such that it is thinner adjacent to the channel and thicker below the channel. Such a combination of a doped region and undoped region with a reversed doping profile reduces both R_{ON} and DIBL at the same time. Hence, embodiments of the present invention provide for a transistor with improved performance.

A first aspect of the present invention includes a semiconductor structure comprising: a silicon substrate; a P-type field effect transistor (PFET) disposed on the silicon substrate; a sigma cavity formed in the silicon substrate adjacent to the PFET, wherein the sigma cavity comprises a shape comprised of a plurality of vertices, including channel vertices, and major segments, the sigma cavity further comprising: a first doped epitaxial layer disposed inside the sigma cavity, wherein the first doped epitaxial layer has a first thickness at the channel vertices and a second thickness at midpoints of the major segments, wherein the first thickness is greater than the second thickness; an undoped epitaxial layer disposed on the first doped epitaxial layer; and a second doped epitaxial layer disposed on the undoped epitaxial layer.

A second aspect of the present invention includes a semiconductor structure comprising: a silicon substrate; an N-type field effect transistor (NFET) disposed on the silicon substrate, a sigma cavity formed in the silicon substrate adjacent to the NFET, wherein the sigma cavity comprises a shape comprised of a plurality of vertices, including channel vertices, and major segments, the sigma cavity further comprising: a first doped epitaxial layer disposed inside the sigma cavity, wherein the first doped epitaxial layer has a first thickness at the channel vertices and a second thickness at midpoints of the major segments, wherein the first thickness is greater than the second thickness; an undoped epitaxial layer disposed on the first doped epitaxial layer; and a second doped epitaxial layer disposed on the undoped epitaxial layer.

A third aspect of the present invention includes a method for fabricating a semiconductor structure, comprising: forming a sigma cavity in a silicon substrate, the sigma cavity disposed adjacent to a transistor, and having an interior surface comprising: forming a first doped layer on the interior surface of the sigma cavity; forming an undoped layer disposed on the first doped layer; and forming a second doped layer disposed on the undoped layer.

### BRIEF DESCRIPTION OF THE DRAWINGS

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity. Furthermore, for clarity, some reference numbers may be omitted in certain drawings.

Features of this invention will be more readily understood from the following detailed description of the various aspects of the invention taken in conjunction with the accompanying drawings in which:

FIG. 1 is a semiconductor structure at a starting point for illustrative embodiments of the present invention;

FIG. 2 is a semiconductor structure after a subsequent processing step of forming a first doped layer;

FIG. 3 is a semiconductor structure after a subsequent processing step of forming an undoped layer;

FIG. 4 is a semiconductor structure after a subsequent processing step of forming a second doped layer;

FIG. 5 is a semiconductor structure after a subsequent processing step of forming silicide regions on the second doped layer; and

FIG. 6 is a flowchart indicating process steps for illustrative embodiments.

### DETAILED DESCRIPTION

Exemplary embodiments will now be described more fully herein with reference to the accompanying drawings, in which exemplary embodiments are shown. Exemplary embodiments of the invention provide an improved method and structure for a transistor with reduced DIBL and R_{ON}. A sigma cavity is formed in a semiconductor substrate adjacent to a transistor. The sigma cavity is filled with an epitaxially grown semiconductor material that also serves as a stress-inducing region for the purposes of increasing carrier mobility. The epitaxially grown semiconductor material is doped with a reverse doping profile. A lightly doped region lines the interior of the sigma cavity, followed by an undoped region, followed by a heavily doped region. The shape of the lightly doped region is such that it is thicker adjacent to the channel, and thinner below the channel. The shape of the undoped region is such that it is thinner adjacent to the channel and thicker below the channel. Such a combination of a doped region and undoped region with a reversed doping profile reduces both R_{ON} and DIBL at the same time. The profile of the lightly doped region results primarily due to the surface energy reduction at the beginning of the epitaxial growth state. The grown material first fills the tip adjacent to the channel, and the area at the bottom, while there is little or no growth on the sidewall below the channel, which is a flat 111 surface. The profile of the undoped region results primarily due to the growth rate difference on different crystalline planes. The growth rate from the bottom <100> direction is usually greater than that from side walls <110> and <111> direction. This facilitates a non-uniform doping with an undoped region that reduces both the R_{ON} and DIBL at the same time. Hence, embodiments of the present invention provide for a transistor with improved performance.

It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure (e.g., a first layer), is present on a second element, such as a second structure (e.g. a second layer), wherein intervening elements, such as an interface structure (e.g. interface layer), may be present between the first element and the second element.

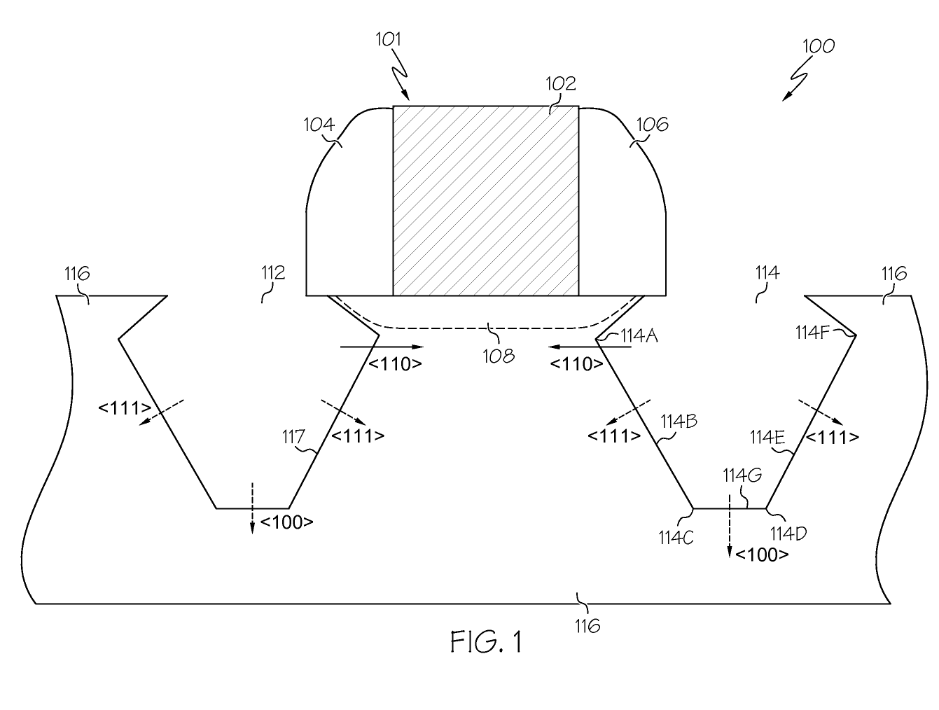

FIG. 1 is a semiconductor structure 100 at a starting point for embodiments of the present invention. Semiconductor structure 100 comprises a crystalline silicon substrate 116. Silicon substrate 116 may be a bulk silicon substrate, or a silicon-on-insulator (SOI) substrate. Disposed on substrate 116 is transistor 101. Transistor 101 has a gate region 102 and spacers 104 and 106 adjacent gate region 102. Gate region 102 may comprise polysilicon, metal, or a combination of the two. Additionally, a gate dielectric (not shown) may be formed below the gate region 102. The spacers 104 and 106 may be comprised of oxide, nitride, or other suitable material. In some cases, multiple spacers comprising various regions of oxide and nitride may be used. In some embodiments, transistor 101 may be a P-type field effect transistor (PFET). In other embodiments, transistor 101 may be an N-type field effect transistor (NFET). Channel region 108 is disposed under the gate 102.

Adjacent to transistor 101 is cavity 112 and cavity 114. The cavities are formed in the substrate 116, and have interior surface 117. Cavities 112 and 114 are referred to as sigma cavities, and, as indicated for cavity 114, have a cross sectional shape comprising vertices 114A, 114C, 114D, and 114F. Vertices 114A and 114C are joined by major segment 114B and vertices 114D and 114F are joined by major segment 114E. Vertices 114C and 114D are joined by base segment 114G. Vertices 114A and 114F are referred to as channel vertices, since they are closest to the level of the channel 108. Sigma cavities 112 and 114 may be formed by a wet etch technique, as is known in the industry. The notation of <100>,<110> and <111> pertain to Miller indices for the silicon substrate. The crystalline structure of the substrate 116 is <111> in the direction perpendicular to the major segments, and is <100> in the direction perpendicular to the base segment, and is <110> in the direction parallel to the base segment.

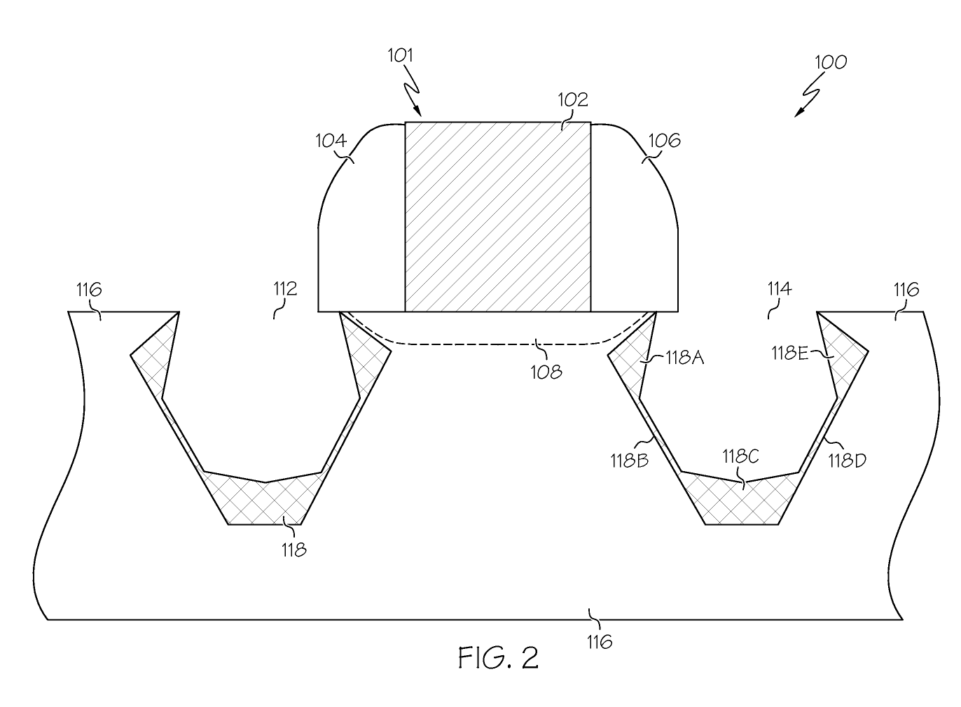

FIG. 2 is semiconductor structure 100 after a subsequent processing step of forming a first doped layer 118 (indicated generally in cavity 112). First doped layer 118 is an in-situ doped epitaxial layer. The epitaxial layer grows at a first rate on <110> silicon and grows at a second rate on <111> silicon. The first rate is faster than the second rate, due to the cavity shape and reduction of surface energy. The growth of the first doped layer 118 is faster near the vertices than at the midpoint of the major segments. Hence, referring to the detailed labeling of cavity 114, the first doped layer comprises thick regions 118A, 118C, and 118E, and thin (close to, or equal to zero) regions 118B, and 118D. Thick regions 118A and 118E are near the channel vertices, and serve to reduce the R_{ON}. The thin regions 118B and 118D are located near the midpoints of the major segments. In some embodiments, the thin regions 118B and 118D range from 0 to 1 nanometer. It is preferable for thin regions 118B and 118D to be as thin as possible, and ideally, zero.

In the embodiments where transistor 101 is a PFET, the first doped layer may be doped with boron. In some embodiments, optionally, the first doped layer may also have carbon dopants added in-situ. The carbon dopants are electrically inactive, and serve to reduce dopant-induced strains caused by the boron dopants, which can reduce boron diffusion.

In the embodiments where transistor 101 is an NFET, the first doped layer may be doped with phosphorous or arsenic. In some embodiments, the dopant concentration of first doped layer 118 ranges from about 1E19 atoms per cubic centimeter to about 5E19 atoms per cubic centimeter. In the embodiments where transistor 101 is a PFET, the first doped layer 118 may be comprised of silicon germanium (SiGe). In the embodiments where transistor 101 is an NFET, the first doped layer may be comprised of silicon carbon (SiC) or silicon carbon phosphorous (SiCP).

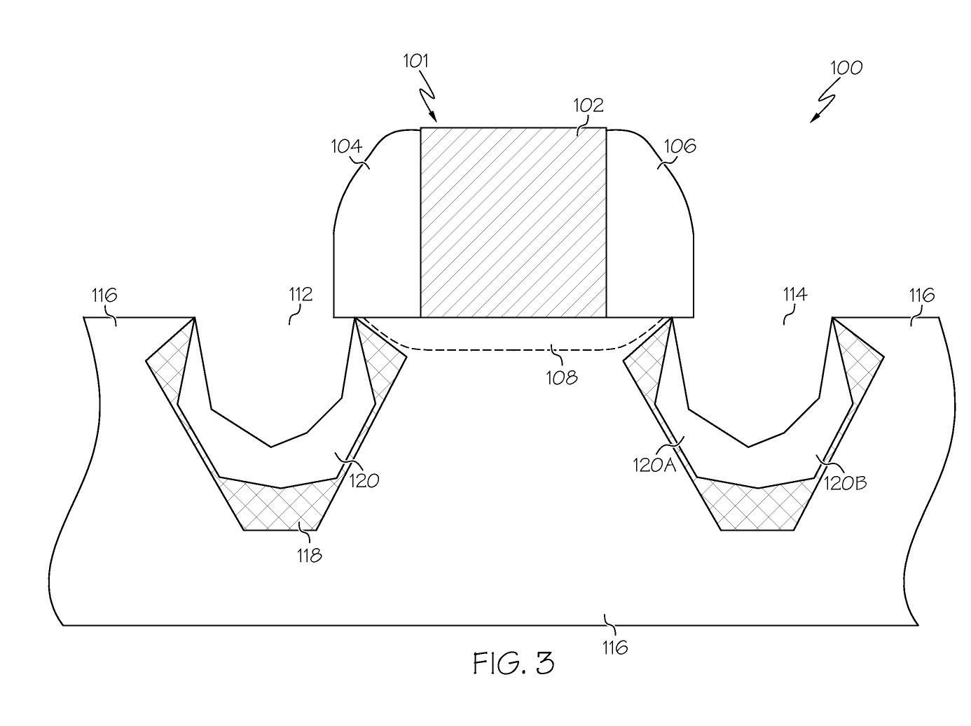

FIG. 3 is semiconductor structure 100 after a subsequent processing step of forming an undoped epitaxial layer 120 (indicated generally in cavity 112). The undoped epitaxial layer may be comprised of the same material as the first doped layer 118. For example, if the first doped layer 118 is comprised of SiGe, then the undoped layer 120 may also be comprised of SiGe. Referring to the detailed labeling of cavity 114, the undoped layer has regions 120A and 120B along the major segments of the cavity 114. The undoped layer has a first thickness at the channel vertices, and a second thickness at the midpoints of the major segments. The first thickness is smaller than the second thickness. This serves to reduce the DIBL.

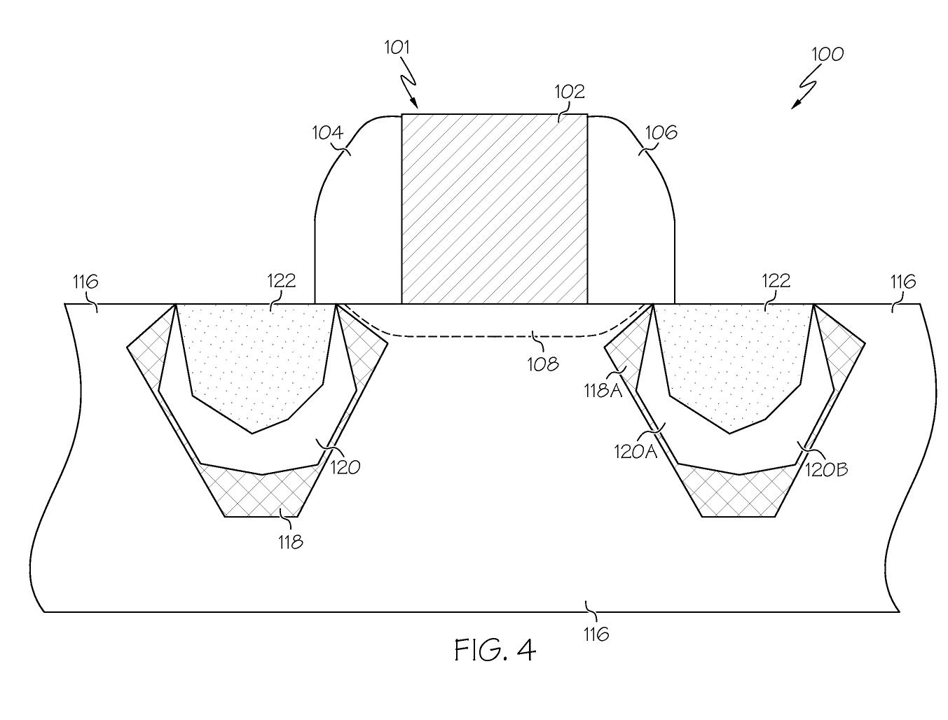

FIG. 4 is semiconductor structure 100 after a subsequent processing step of forming a second doped layer 122. The second doped layer may be comprised of the same material as the first doped layer 118. For example, if the first doped layer 118 is comprised of SiGe, then the second doped layer 122 may also be comprised of SiGe. The second doped layer 122 has a higher dopant concentration than the first doped layer 118. In some embodiments, the dopant concentration of the second doped layer 122 ranges from about 1E20 atoms per cubic centimeter to about 5E20 atoms per cubic centimeter. The second doped layer may be doped with the same dopant species that is present in the first doped layer 118. For example, if boron is used as the dopant in the first doped layer 118, then boron may also be used in the second doped layer 122.

With respect to channel 108, the first doped layer region 118A is adjacent to the channel. The first doped layer has a lower resistance than undoped silicon. Therefore, region 118A serves to lower the R_{ON}. However, if the entire cavity 114 were filled with doped silicon, it creates a problem for the DIBL, as a leakage current can build along the major segments of the cavity. By forming undoped region 120, having thick region 120A disposed below the channel 108, and below first doped layer region 118A, it behaves as an insulator in that region, thereby reducing the DIBL. Hence, what heretofore was a tradeoff between R_{ON} and DIBL is now resolved with a reverse doped profile sigma cavity. The area nearest to the transistor channel 108 is doped (see 118A), which reduces the R_{ON}, whereas the region below doped region 118A, and well below the transistor channel 108 (see 120A), is mostly undoped, which reduces the DIBL. Therefore, embodiments of the present invention serve to improve transistor performance.

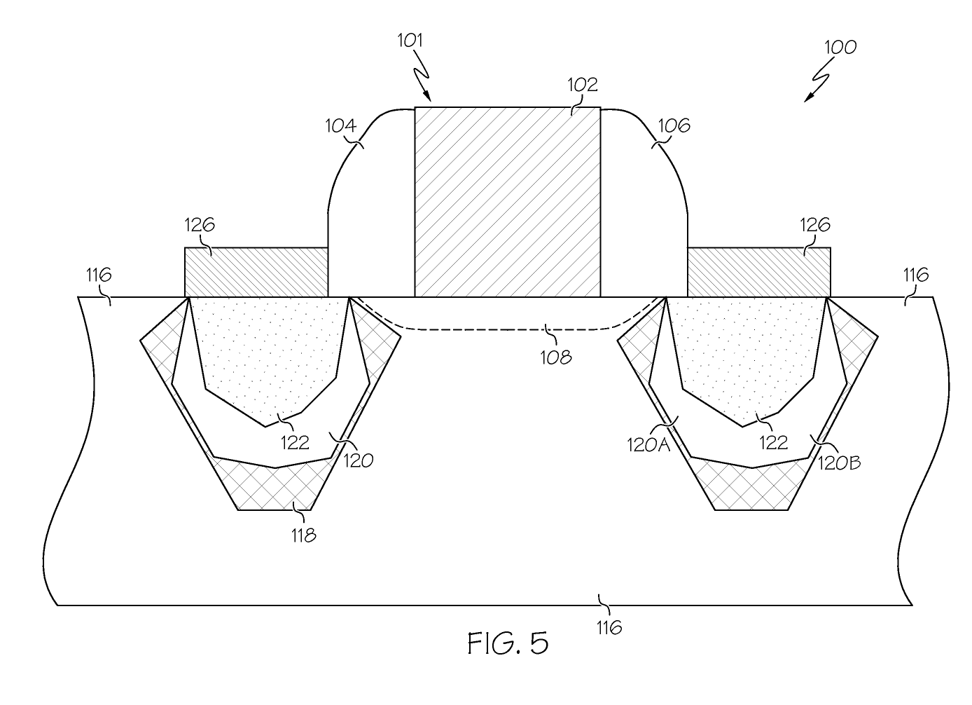

FIG. 5 is semiconductor structure 100 after a subsequent processing step of forming silicide regions 126 on the second doped layer. Silicide regions 126 may serve as raised source/drain (RSD) structure for receiving a metal contact (not shown) to connect transistor 101 to other circuit elements. Silicide regions 126 may be comprised of any metal that is capable of reacting with silicon to form a metal silicide. Examples of such metals include, but are not limited to: Ti, Ta, W, Co, Ni, Pt, Pd and alloys thereof.

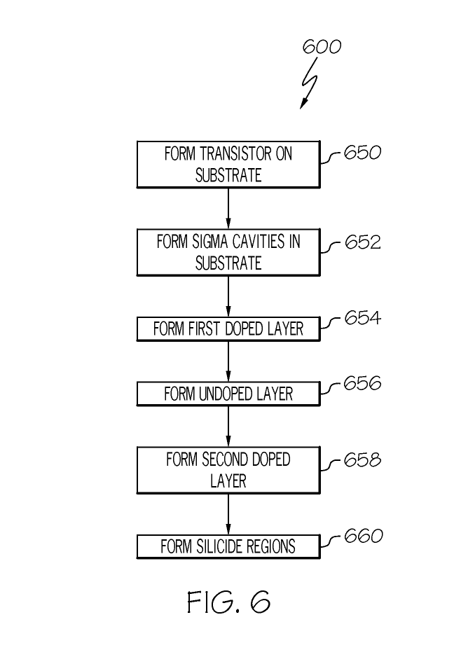

FIG. 6 is a flowchart 600 indicating process steps for illustrative embodiments. In process step 650, a transistor is formed on a silicon substrate (see 101 of FIG. 1). In process step 652, sigma cavities are formed (see 112 and 114 of FIG. 1). This may be accomplished with a wet etch. In process step 654, a first doped layer is formed (see 118 of FIG. 2). This may be accomplished by forming an in situ doped epitaxial layer of SiGe (for PFETs) or SiC or SiCP (for NFETs). One of the purposes of the epitaxial layer is to induce stress on the channel regions (108 of FIG. 1) to improve carrier mobility. Hence, the choice of fill material (SiGe, SiC, or SiCP) depends on the type of transistor (NFET or PFET). This is because the NFET and PFET have carrier mobility enhanced by different types of stress. In process step 656, an undoped epitaxial layer is formed (see 120 of FIG. 3). In process step 658, a second doped layer is formed (see 122 of FIG. 4). In process step 660, silicide regions are formed (see 126 of FIG. 5).

In various embodiments, design tools can be provided and configured to create the datasets used to pattern the semiconductor layers as described herein. For example, data sets can be created to generate photomasks used during lithography operations to pattern the layers for structures as described herein. Such design tools can include a collection of one or more modules and can also include hardware, software, or a combination thereof. Thus, for example, a tool can be a collection of one or more software modules, hardware modules, software/hardware modules, or any combination or permutation thereof. As another example, a tool can be a computing device or other appliance on which software runs or in which hardware is implemented. As used herein, a module might be implemented utilizing any form of hardware, software, or a combination thereof. For example, one or more processors, controllers, application-specific integrated circuits (ASIC), programmable logic arrays (PLA)s, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A semiconductor structure comprising:
a silicon substrate;
a P-type field effect transistor (PFET) disposed on the silicon substrate;
a sigma cavity formed in the silicon substrate adjacent to the PFET, wherein the sigma cavity comprises a shape comprised of a plurality of vertices, including channel vertices, and major segments, the sigma cavity further comprising:
a first doped epitaxial layer disposed inside the sigma cavity, wherein the first doped epitaxial layer has a first thickness at the channel vertices and a second thickness at midpoints of the major segments, wherein the first thickness is greater than the second thickness;
an undoped epitaxial layer disposed on the first doped epitaxial layer; and
a second doped epitaxial layer disposed on the undoped epitaxial layer.

2. The semiconductor structure of claim 1, wherein the first doped epitaxial layer is comprised of SiGe.

3. The semiconductor structure of claim 1, wherein the undoped epitaxial layer has a first thickness at the channel vertices and a second thickness at midpoints of the major segments, wherein the first thickness is smaller than the second thickness.

4. The semiconductor structure of claim 3, wherein the first doped epitaxial layer has a dopant concentration ranging from about 1E19 atoms per cubic centimeter to about 5E19 atoms per cubic centimeter.

5. The semiconductor structure of claim 4, wherein the second doped epitaxial layer has a dopant concentration ranging from about 1E20 atoms per cubic centimeter to about 5E20 atoms per cubic centimeter.

6. The semiconductor structure of claim 5, wherein the first doped epitaxial layer is doped with boron dopants.

7. The semiconductor structure of claim 6, wherein the first doped epitaxial layer further comprises carbon dopants.

8. A semiconductor structure comprising:
a silicon substrate;
an N-type field effect transistor (NFET) disposed on the silicon substrate;
a sigma cavity formed in the silicon substrate adjacent to the NFET, wherein the sigma cavity comprises a shape comprised of a plurality of vertices, including channel vertices, and major segments, the sigma cavity further comprising:
a first doped epitaxial layer disposed inside the sigma cavity, wherein the first doped epitaxial layer has a first thickness at the channel vertices and a second thickness at midpoints of the major segments, wherein the first thickness is greater than the second thickness;
an undoped epitaxial layer disposed on the first doped epitaxial layer, and
a second doped epitaxial layer disposed on the undoped epitaxial layer.

9. The semiconductor structure of claim 8, wherein the first doped epitaxial layer is comprised of SiC.

10. The semiconductor structure of claim 8, wherein the first doped epitaxial layer is comprised of SiCP.

11. The semiconductor structure of claim 8, further comprising a silicide region disposed on the second doped epitaxial layer.

12. The semiconductor structure of claim 8, wherein the first doped epitaxial layer has a dopant concentration ranging from about 1E19 atoms per cubic centimeter to about 5E19 atoms per cubic centimeter.

13. The semiconductor structure of claim 12, wherein the second doped epitaxial layer has a dopant concentration ranging from about 1E20 atoms per cubic centimeter to about 5E20 atoms per cubic centimeter.

14. The semiconductor structure of claim 8, wherein the first doped epitaxial layer comprises phosphorous dopants.

15. The semiconductor structure of claim 8, wherein the undoped epitaxial layer has a first thickness at the channel vertices and a second thickness at midpoints of the major segments, wherein the first thickness is smaller than the second thickness.

16. A method for fabricating a semiconductor structure, comprising:
forming a sigma cavity in a silicon substrate, the sigma cavity disposed adjacent to a transistor, and having an interior surface comprising:
forming a first doped layer on the interior surface of the sigma cavity;
forming an undoped layer disposed on the first doped layer; and
forming a second doped layer disposed on the undoped layer.

17. The method of claim 16, wherein forming a first doped layer comprises forming a boron in situ doped epitaxial layer.

18. The method of claim 16, wherein forming a first doped layer comprises forming a phosphorous in situ doped epitaxial layer.

19. The method of claim 17, further comprising adding carbon dopants to the first doped layer.

20. The method of claim 16, wherein forming a first doped layer comprises forming a doped layer having a dopant concentration ranging from about 1E19 atoms per cubic centimeter to about 5E19 atoms per cubic centimeter.
